(19) United States
(12) Patent Application Publication
(10) Pub. No.: US 2024/0194489 A1
(43) Pub. Date: Jun. 13, 2024

(54) PLASMA PROCESSING METHOD

(71) Applicant: Hitachi High-Tech Corporation, Minato-ku, Tokyo (JP)

(72) Inventors: Yusuke Nakatani, Tokyo (JP); Yasushi Sonoda; Motohiro Tanaka

(21) Appl. No.: 17/908,177

(22) PCT Filed: Oct. 22, 2021
(86) PCT No.: PCT/JP2021/039032

§ 371 Date: Aug. 30, 2022

(51) Int. Cl. H01L 21/311; H01L 21/02; H01L 21/28; H01L 29/423; H01L 29/49; H01L 29/66

(52) U.S. Cl. CPC H01L 21/31122; H01L 21/02181; H01L 21/28255; H01L 29/42392; H01L 29/4908; H01L 29/66439

(57) ABSTRACT

HfO₂ is to be selectively laterally etched and to SiGe. In order to manufacture a device in a next generation three-dimensional structure such as GAA, in a plasma processing method that laterally etches HfO₂ using a vacuum processing apparatus that is capable of perform radical etching, a flow rate ratio is set such that an SiCl₄ gas is added to a BCl₃ gas, a flow rate ratio of the SiCl₄ gas at this time is lower than a flow rate ratio of the BCl₃ gas, and an SiClₓ deposition to be deposited on SiGe is larger than an SiClₓ deposition to be deposited on HfO₂, and thus HfO₂ is selectively etched to SiGe.

### TECHNICAL FIELD

The present invention relates to a plasma processing method.

### BACKGROUND ART

In the fabrication process steps of a semiconductor device, response to downscaling or integration of components included in the semiconductor device is requested. For example, in integrated circuits or nano-electromechanical systems, the shrinkage of a structure to nanoscale is further propelled.

Generally, in the fabrication process steps of the semiconductor device, in order to form fine patterns, a lithography technique is used. This technique is a technique in which patterns of a device structure are applied on a resist layer, and a substrate exposed from the patterns of the resist layer is selectively etched and removed. In the subsequent process steps, another material is deposited in an etching region, and then an integrated circuit can be formed.

More specifically, nowadays, requests for power saving and speedups to the semiconductor device are increased from the market, and the tendencies of sophistication and high integration of the device structure are noticeable. For example, in logic devices, the application of GAA (Gate All Around) in which channels are formed of stacked nanowires are studied. In the etching process steps of GAA, in addition to perpendicular processing by conventional anisotropic etching, lateral processing by isotropic etching is necessary in order to form nanowires.

Here, anisotropic etching means etching using the ion assist reaction that promotes the reaction to a radical with ions, and isotropic etching means etching mainly using the surface reaction. In the manufacture of next-generation three-dimensional devices such as GAA, there are a large number of process steps that request lateral etching by isotropic etching. For example, a technique is necessary, which highly selectively laterally etches hafnium oxide HfO₂ of a high relative dielectric constant used for gate insulating films to silicon germanium SiGe.

To such a request, in PTL 1, a technique is proposed in which at least one kind of a non-reactive gas such as argon, an oxygen atom supply gas such as oxygen, and an oxidizing gas such as nitrogen oxide is activated in a remote plasma generator to form a gas containing an active species, and this gas is introduced into a chamber together with a halogen-based gas such as boron trichloride BCl₃ to etch HfO₂.

Moreover, in PTL 2, a technique is proposed in which HfO₂ is etched with plasma generated from an etching gas mixture containing halogen-containing gas.

### CITATION LIST

### Patent Literature

PTL 1: Japanese Patent Application Laid-Open No. 2006-339523
PTL 2: Japanese Patent Application Laid-Open No. 2009-21584

### SUMMARY OF INVENTION

### Technical Problem

In order to laterally etch hafnium oxide HfO₂ used for a gate insulating film, it is necessary to shield ions that advance etching in the vertical direction to perform etching with a radical alone. However, since the technique described in PTL 2 is not etching with the radical shielding ions, it is considered that etching in the vertical direction by ion injection proceeds.

Moreover, in the manufacture of next-generation three-dimensional devices such as GAA, highly selective etching of hafnium oxide HfO₂ to silicon germanium SiGe is requested. However, neither PTL 1 nor PTL 2 refers to a technique of selectively etching hafnium oxide HfO₂ to silicon germanium SiGe.

### Solution to Problem

In order to manufacture of a device in a next generation three-dimensional structure such as GAA, a solution to the problems is to be achieved by a plasma processing method that laterally etches hafnium oxide HfO₂ using a vacuum processing apparatus that is capable of perform radical etching in which a flow rate ratio is set such that a silicon tetrachloride SiCl₄ gas is added to a boron trichloride BCl₃ gas, and a flow rate ratio of the silicon tetrachloride SiCl₄ gas at this time is lower than a flow rate ratio of the boron trichloride BCl₃ gas and an SiCl_{z} deposition to be deposited on the silicon germanium SiGe larger than an SiClₓ deposition to be deposited on the hafnium oxide HfO₂, and thus the hafnium oxide HfO₂ is selectively etched to silicon germanium SiGe.

Moreover, a solution to the problems is to be achieved in the plasma processing method, the flow rate ratio of the silicon tetrachloride SiCl₄ gas is set to 3 to 20%.

### Advantageous Effects of Invention

According to the present invention, it is possible to provide a plasma processing method that is capable of selectively laterally etching hafnium oxide HfO₂ and to silicon germanium SiGe.

### BRIEF DESCRIPTION OF DRAWING

FIG. 1 is a schematic cross-sectional view of the overall structure of a vacuum processing apparatus according to a first embodiment of the present invention.

FIG. 2 is a plan view showing a shield plate according to the first embodiment of the present invention.

FIG. 3 is a graph showing the flow rate ratio dependence of the etching rates of HfO₂ and SiGe on a SiCl₄ gas in the mixed gas system of a BCl₃ gas and the SiCl₄ gas according to the first embodiment of the present invention.

FIG. 4 is a graph showing the flow rate ratio dependence of the etching rate selection ratio of HfO₂ to SiGe on the SiCl₄ gas in the mixed gas system of the BCl₃ gas and the SiCl₄ gas according to the first embodiment of the present invention.

### DESCRIPTION OF EMBODIMENTS

In the following, an embodiment of the present invention will be described with reference to the drawings.

### First Embodiment

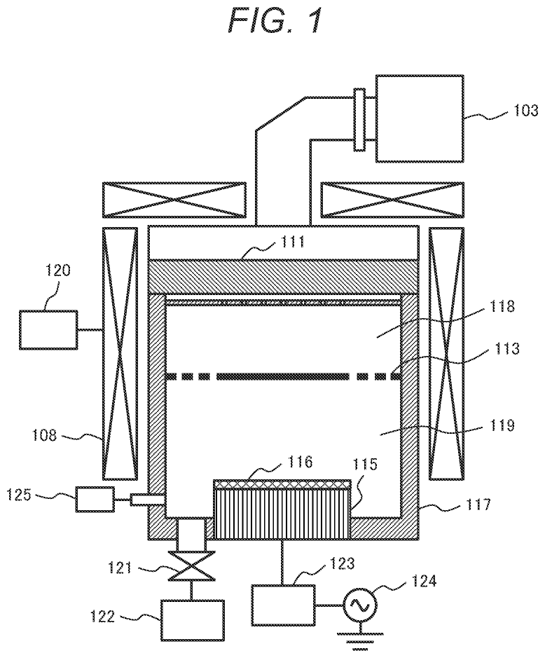

FIG. 1 is a schematic cross-sectional view of the overall structure of a vacuum processing apparatus according to a first embodiment of the present invention.

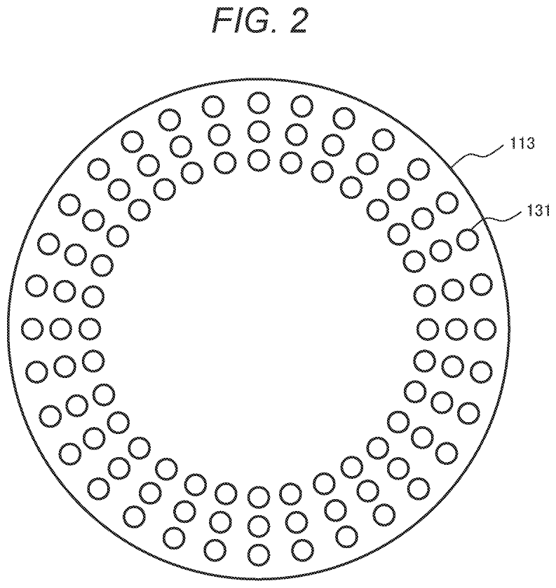

FIG. 2 is a plan view showing a shield plate according to the first embodiment of the present invention.

The schematic cross-sectional view showing the overall structure of the vacuum processing apparatus according to the first embodiment of the present invention is shown in FIG. 1. The apparatus of the present embodiment is capable of generating plasma in a vacuum processing chamber 117 by electron cyclotron resonance (ECR) with a microwave at 2.45 GHz supplied from a magnetron 103 that is a radio frequency power supply to the vacuum processing chamber 117 through a dielectric window 111 and a magnetic field created by a solenoid valve coil 108 that is a magnetic field forming mechanism. Such a vacuum processing apparatus is referred to as an ECR plasma processing apparatus.

Moreover, a radio frequency power supply 124 is connected to a sample 116 placed on a sample stage 115 through a matching box 123. The inside of the vacuum processing chamber 117 is connected to a pump 122 through a valve 121, and the internal pressure can be adjusted by the degree of opening of the valve 121.

Moreover, the present vacuum processing apparatus has a shield plate 113 that is made of silica shown in FIG. 2 in the inside of the vacuum processing chamber 117. On the shield plate 113, through holes 131 having the same hole diameter are uniformly disposed on the outer peripheral part. The term “uniform” in the present embodiment means that the through holes 131 having the center point on the same circle are disposed at equal pitches in the circumferential direction when concentric circles having the equal diameter difference are drawn (including the case where the radius is zero). The shield plate 113 divides the inside of the vacuum processing chamber 117 into a first space 118 and a second space 119, and a pressure gage 125 is connected to the inside of the second space 119.

The plasma processing apparatus used in the present embodiment has characteristics that in the case where the frequency of a microwave is 2.45 GHz, plasma can be generated near the surface of a magnetic field strength of 0.0875 T. Therefore, when the magnetic field is adjusted such that a plasma generation region is located between the shield plate 113 and the dielectric window 111 (the first space 118), plasma can be generated on the dielectric window 111 side of the shield plate 113, and most of the generated ions fail to pass the shield plate 113, and thus it is possible to apply a radical alone to the sample 116. At this time, in the sample 116, isotropic etching mainly using a surface reaction with the radical alone proceeds.

To this, when the magnetic field is adjusted such that the plasma generation region is located between the shield plate 113 and the sample 116 (the second space 119), plasma can be generated on the sample 116 side from the shield plate 113, and both of ions and a radical can be supplied to the sample 116. At this time, in the sample 116, anisotropic etching using an ion assist reaction that promotes the reaction to a radical with ions proceeds.

Note that the adjustment or switching (upward or downward) of the height position of the plasma generation region to the height position of the shield plate 113, the adjustment of the period for which the height positions are retained, or the like can be performed using a controller 120.

In the first embodiment of the present invention, the magnetic field is adjusted such that the plasma generation region is located between the shield plate 113 and the dielectric window 111 (the first space 118), and the sample 116 is laterally etched by isotropic etching mainly using the surface reaction with the radical alone. Into the inside of the vacuum processing chamber 117, a mixed gas of a boron trichloride BCl₃ gas and a silicon tetrachloride SiCl₄ gas is introduced to generate plasma, a radical generated from the plasma generated in the first space 118 passes the through holes 131 disposed on the shield plate 113 and reaches the sample 116, and thus etching proceeds. At this time, the flow rate ratios of the BCl₃ gas and the SiCl₄ gas are adjusted such that the etching rate at which the sample 116 is hafnium oxide HfO₂ is higher than the etching rate at which the sample 116 is silicon germanium SiGe, i.e., HfO₂ is selectively etched to SiGe. The sample 116 is a substrate for manufacturing a semiconductor used for the manufacture of next-generation three-dimensional devices such as GAA (Gate All Around). In the manufacture of next-generation three-dimensional devices such as GAA, there are a large number of process steps that request lateral etching by isotropic etching. For example, HfO₂ of a high relative dielectric constant used for a gate insulating film is highly selectively laterally etched to SiGe. In the sample 116, HfO₂ is to be etched in the perpendicular direction to a direction in which SiGe is stacked. Consequently, in the case where a plurality of layers of SiGe is stacked in the vertical direction that is a perpendicular direction to the surface in the horizontal direction of the semiconductor substrate as the sample 116, HfO₂ is to be etched in the lateral direction that is the perpendicular direction to the vertical direction (i.e., the horizontal direction).

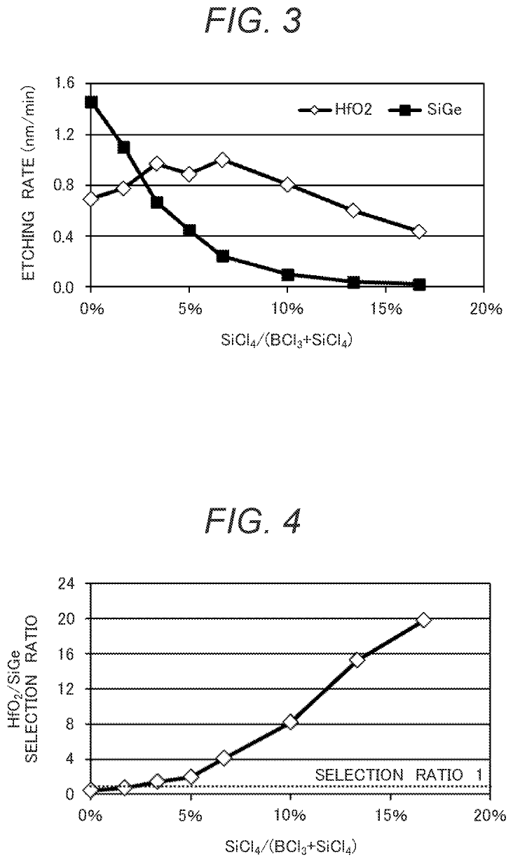

FIG. 3 is a graph showing the flow rate ratio dependence of the etching rates of HfO₂ and SiGe on the SiCl₄ gas in the mixed gas system of the BCl₃ gas and the SiCl₄ gas according to the first embodiment of the present invention.

When etching is performed in which the flow rate ratio of the SiCl₄ gas is 0%, i.e., with the BCl₃ gas alone, the etching rate of SiGe is higher than the etching rate of HfO₂, which leads to no selective etching of HfO₂ to SiGe. Hence, the SiCl₄ gas is added to increase the flow rate ratio of the SiCl₄ gas to 3% or more, the etching rate of HfO₂ becomes higher than the etching rate of SiGe, which allows selective etching of HfO₂ to SiGe. In other words, HfO₂ is etched using a mixed gas of the BCl₃ gas and the SiCl₄ gas. A configuration may be provided in which the flow rate of the SiCl₄ gas is smaller than the flow rate of the BCl₃ gas. Furthermore, since the flow rate ratio of the SiCl₄ gas is increased to deposit a SiClₓ deposition, which inhibits etching, both of the etching rates of HfO₂ and SiGe are reduced.

FIG. 3 is a graph until when the flow rate ratio of SiCl₄ is about 17%. When a graph of the etching rate is further extrapolated to a region in which the flow rate ratio of SiCl₄ is high, it is assumed that the etching rate of HfO₂ is higher than the etching rate of SiGe until when the flow rate ratio of SiCl₄ is about 20%, and the etching rate of HfO₂ becomes negative when the flow rate ratio of SiCl₄ reaches 20% or more, and etching will stop. Consequently, in the BCl₃+SiCl₄ gas system, the flow rate ratio of the SiCl₄ gas is set to a value within the range of 3 to 20%, and thus it is possible to selectively etch HfO₂ to SiGe. Although the addition of the SiCl₄ gas generates an SiClₓ deposition on the sample 116 and reduces the etching rate, an SiClₓ deposition to be deposited on SiGe is larger than HfO₂ in the region in which the flow rate ratio of SiCl₄ ranges from 3 to 20%, and thus it is possible to selectively etch HfO₂ to SiGe. In other words, it can be said that the ratio of the flow rate of the SiCl₄ gas to the flow rate of the mixed gas is a value at which the thickness of the deposited film of SiClₓ to be deposited on SiGe is thicker than the thickness of the deposited film of SiClₓ to be deposited on HfO₂. Note that the pressure of the second space 119 in the vacuum processing chamber 117 at this time is 1 to 8 mTorr, and the temperature of the sample stage 115 on which the sample 116 is placed is 50° C. or more.

FIG. 4 is a graph showing the flow rate ratio dependence of the etching rate selection ratio of HfO₂ to SiGe on the SiCl₄ gas in the mixed gas system of the BCl₃ gas and the SiCl₄ gas according to the first embodiment of the present invention. The selection ratio is found by dividing the etching rate of HfO₂ by the etching rate of SiGe. In the graph, a line expressing that the etching rate selection ratio of HfO₂ to SiGe is one is depicted by a broken line. When this selection ratio is one or more, HfO₂ is selectively etchable to SiGe. It is shown that in the mixed gas system of the BCl₃ gas and the SiCl₄ gas, the selection ratio becomes one or more and HfO₂ is selectively etchable to SiGe when the flow rate ratio of the SiCl₄ gas is 3% or more. FIG. 4 is a graph until when the flow rate ratio of the SiCl₄ gas is about 17%. As in the assumption in FIG. 3, the selection ratio becomes one or more until when the flow rate ratio of the SiCl₄ gas is about 20%, and HfO₂ is selectively etchable to SiGe.

The present invention is usable for a plasma processing method that selectively etches HfO₂, which is a gate insulating film in a Gate All Around structure, to SiGe, with plasma, and a plasma processing method that selectively etches HfO₂ to SiGe with plasma.

The foregoing embodiment describes the present invention in detail for easy understanding, which does not necessarily limit the present invention to ones having all the configurations having been described.

### REFERENCE SIGNS LIST

103 . . . magnetron,
108 . . . solenoid valve coil,
111 . . . dielectric window,
113 . . . shield plate,
115 . . . sample stage,
116 . . . sample,
117 . . . vacuum processing chamber,
118 . . . first space,
119 . . . second space,
120 . . . controller,
121 . . . valve,
122 . . . pump,
123 . . . matching box,
124 . . . radio frequency power supply,
125 . . . pressure gage,
131 . . . through hole on shield plate 113

1. A plasma processing method that selectively etches HfO₂ that is a gate insulating film in a Gate All Around structure to SiGe with plasma,
wherein the HfO₂ is etched using a mixed gas of a BCl₃ gas and an SiCl₄ gas; and
a flow rate of the SiCl₄ gas is smaller than a flow rate of the BCl₃ gas.

2. The plasma processing method according to claim 1,
wherein the HfO₂ is etched in a perpendicular direction to a direction in which the SiGe is stacked.

3. The plasma processing method according to claim 1,
wherein a ratio of the flow rate of the SiCl₄ gas to a flow rate of the mixed gas is a value at which a thickness of a deposited film to be deposited on the SiGe is thicker than a thickness of a deposited film to be deposited on the HfO₂.

4. The plasma processing method according to claim 2,
wherein a ratio of the flow rate of the SiCl₄ gas to a flow rate of the mixed gas is a value at which a thickness of a deposited film to be deposited on the SiGe is thicker than a thickness of a deposited film to be deposited on the HfO₂.

5. The plasma processing method according to claim 4,
wherein the ratio of the flow rate of the SiCl₄ gas to the flow rate of the mixed gas is a value within a range of 3 to 20%.

6. A plasma processing method that selectively etches HfO₂ to SiGe with plasma,
wherein the HfO₂ is etched using a mixed gas of a BCl₃ gas and an SiCl₄ gas; and
a flow rate of the SiCl₄ gas is smaller than a flow rate of the BCl₃ gas.
